(19) United States
(12) Patent Application Publication
(10) Pub. No.: US 2021/0080426 A1
(43) Pub. Date: Mar. 18, 2021

(54) SENSOR AND METHOD

(71) Applicant: KABUSHIKI KAISHA TOSHIBA, Minato-ku (JP)

(72) Inventor: Tatsuro SAITO, Kawasaki (JP)

(73) Assignee: KABUSHIKI KAISHA TOSHIBA, Minato-ku (JP)

(21) Appl. No.: 16/805,897

(22) Filed: Mar. 2, 2020

(30) Foreign Application Priority Data
Sep. 13, 2019 (JP) 2019-167614

(51) Int. Cl. G01N 27/414

(52) U.S. Cl. CPC G01N 27/4146; H01L 29/1606

(57) ABSTRACT

According to one embodiment, a sensor includes a first electrode, a second electrode, a channel electrically connected to the first electrode and the second electrode and an insulating layer which covers at least the first electrode and the second electrode and comprises an opening above the channel. A length of the opening along the second direction is equivalent to or greater than the length of the channel along the second direction.

### CROSS-REFERENCE TO RELATED APPLICATIONS

This application is based upon and claims the benefit of priority from Japanese Patent Application No. 2019-167614, filed Sep. 13, 2019, the entire contents of which are incorporated herein by reference.

### FIELD

Embodiments described herein relate generally to a sensor and a method.

### BACKGROUND

Sensors adapting electrochemical reactions comprise a channel provided on a substrate, and two electrodes connected to both ends of the channel. In such sensors, current flowing between two electrodes is measured, and thus variation in physical properties, such as electrical conductivity or electric resistance, of the channel created by binding or approaching of an analyte to the channel is detected. Thus, the analyte can be detected. There is a demand of such a sensor adapting an electrochemical reaction which can detect a target material at high sensitivity.

### BRIEF DESCRIPTION OF THE DRAWINGS

FIG. 1 is a cross section showing an example of a sensor of the first embodiment.

FIG. 2, part (a) is a plan view showing the example of the sensor of the first embodiment, and part, (b) is an enlarged view of an enclosure B in part (a).

FIG. 3 is a flow chart illustrating an example of a detection method which employs the sensor of the first embodiment.

FIG. 4 is a cross section showing an example of the sensor of the first embodiment while it is used.

FIG. 5 is a plan view showing an example of a sensor of the second embodiment.

FIG. 6 is an enlarged view of an enclosure X in FIG. 5.

FIG. 7, part (a) is a cross section showing an example of a sensor of the third embodiment, and part (b) is a plan view thereof.

FIG. 8 is a plan view showing an example of a sensor of the fourth embodiment.

### DETAILED DESCRIPTION

In general, according to one embodiment, a sensor comprises a first electrode, a second electrode, a channel electrically connected to the first electrode and the second electrode and an insulating layer which covers at least the first electrode and the second electrode. The insulating layer comprises an opening above the channel. When viewed from a direction intersecting a first direction and a second direction, the first direction is a direction towards the second electrode from the first electrode, and the second direction being a direction intersecting the first direction, a length of the opening along the second direction is equivalent to or greater than the length of the channel along the second direction.

Various embodiments will now be described with reference to drawings. The drawings are schematic diagrams of the embodiments to assist understanding thereof, in which shapes, measurements, ratios and the like may be different from actual ones, but the designs thereof may be changed as needed in view of the following explanations and well-known techniques.

### First Embodiment

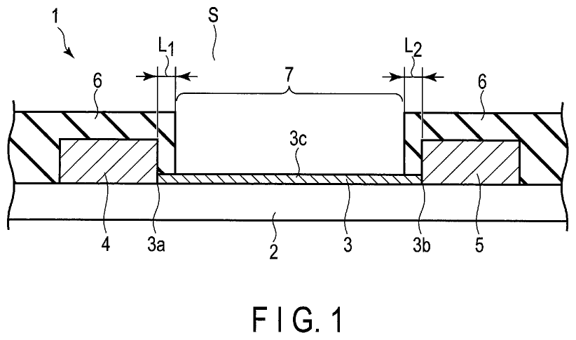

As shown in FIG. 1, a sensor 1 according to the first embodiment comprises a substrate 2, a first electrode 4, a second electrode 5, a film-like channel 3, and an insulating layer 6. The channel 3 is provided on a surface of the substrate 2, one end 3a of the channel 3 is electrically connected to the first electrode 4 and another end 3b is connected to the second electrode 5. Through the channel 3, current flows between the first electrode 4 and the second electrode 5. The insulating layer 6 covers the first electrode 4 and the second electrode 5. In the insulating layer 6, an opening 7 is formed above one surface 3c of the channel 3.

Here, such an expression, “electrically connected” is meant that current can flow between two members connected to each other. For example, they may be in direct contact with each other or may be connected via conductive wiring or the like. Moreover, in this specification, the phrases “provided above” a member covers a case where it is provided on an upper surface of the member to be in contact therewith, or above the member with a gap therebetween or via some other member interposed therebetween.

A space S to accommodate a sample is provided on the surface 3c side the sensor 1. For example, the space S may be formed by wall portions standing around the circumference of the sensor 1 and a ceiling portion configured to connect top of the wall portions. Or the space S may have a shape of a flow passage. The space S may be formed liquid-tight and airtight. When a sample is accommodated inside the space S, and the sample enters the opening 7 and is disposed on the surface 3c of the channel 3.

The insulating layer 6 covers at least the first electrode 4 and the second electrode 5. Here, the covering refers to cover surfaces of the both electrodes, excluding sides contacting with the substrate, with such a thickness to prevent the electrodes from being in contact with the sample, thereby preventing the sample, the first electrode 4 and the second electrode 5 from being electrically connected each other (the occurrence of leakage current), and to prevent corrosion of the first electrode 4 and the second electrode 5 by the sample, and the like.

Thus, the opening 7 is formed so that, in the one end 3a and the other end 3b of the channel 3, there are regions overlapping with the insulating layer 6 which covers each of the first electrode 4 and the second electrode 5. A length L1 of the region overlapping the insulating layer 6 on the side of the end 3a of the channel 3, and a length L2 of the region overlapping the insulating layer 6 on a side of the other end 3b will be described later in detail.

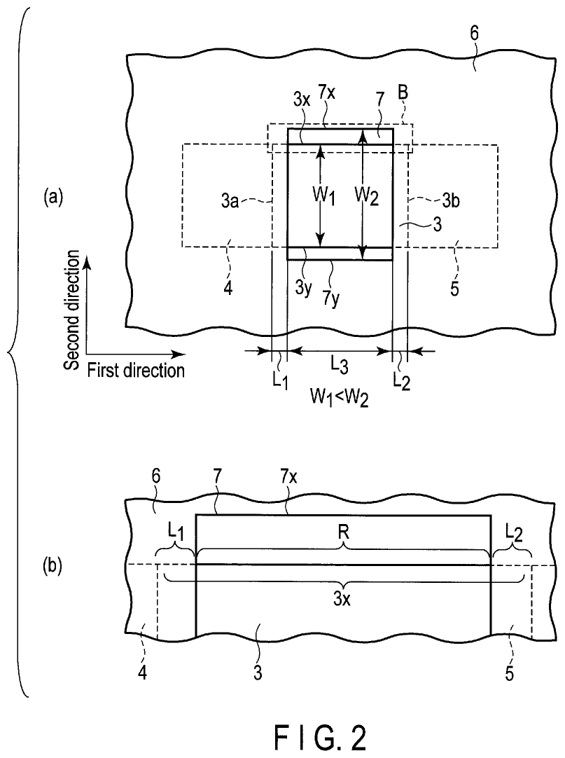

When the sensor 1 is viewed in plain view, the channel 3 is a rectangular, as shown FIG. 2, part (a). The first electrode 4 and the second electrode 5 are connected to parallel two edges (corresponding to the one end 3a and the other end 3b of the channel 3) respectively.

The opening 7 is also rectangular. The opening 7 is formed so that the parallel two edges of the opening 7 are parallel to two edges of the channel 3 (the one end 3a and the other end 3b).

It suffices if the rectangle is substantially rectangular. For example, the four corners may not strictly be right-angled and may be allowed to 90°±10°. Even for an approximately rectangle, two sides facing each other are regarded as “parallel”.

The insulating layer 6 covers, for example, the first electrode 4 and the second electrode 5, and also covers a portion of the substrate 2, where the channel 3 is not formed.

When a direction towards the other end 3b from the one end 3a of the channel 3 is set as the first direction, and a direction intersecting therewith is set as the second direction, the opening 7 is formed so that a length W2 of the opening 7 along the second direction is greater than a length W1 of the channel 3 along the second direction (W1<W2). Here, the intersecting is meant intersecting perpendicular.

Moreover, the plan view is meant the case viewed from a direction perpendicular to the first direction and the second direction.

Positional relation of an edge 3x in one end of the channel 3 along the second direction and an edge 7x in one end of the opening 7 along the second direction will be explained in detail using FIG. 2, part (b), which is an enlarged view of enclosure B shown in FIG. 2, part (a).

The edge 3x includes: a region having a length L1 and a length L2, which overlaps the insulating layer 6; and a region therebetween (which is referred to as “the first region R” below). The edge 7x is formed so that the first region R is located inside the opening 7. Similarly, an edge 7y in the other end of the opening 7 along the second direction is disposed so that the first region R of other edge 3y of the channel 3 is located inside the opening 7.

On the other hand, positions of two edges in ends of the opening 7 along the first direction defining the length L3 which is the length of the opening 7 along the first direction are not particularly limited. But it is preferable that, for example, L3 be set so that in the region of the surface 3c of the channel 3 which is not in contact with the first electrode 4 and the second electrode 5, the area overlapping the insulating layer 6 is less than 50% of the region. However, L3 should preferably be longer because the detection sensitivity of the sensor 1 may be further improved. For example, it is more preferable that the area which overlaps the insulating layer 6 is less than 20% of the region.

Or, L3 may be determined depending on the lengths L1 and L2 of the regions which overlap the insulating layer 6 of the channel 3. For example, L3 is determined based on L1 and L2 which are set up so that the insulating layer 6 has such a degree of thickness that the first electrode 4 and the second electrode 5 are not brought into contact with the sample. For example, it is preferable that the lengths L1 and L2 each may be 1 nm to 50 μm.

The dimensions of each of the members can be measured, for example, by transmission electron microscope (TEM) analysis.

The substrate 2 is, for example, a rectangular plate. The material of the substrate 2 is, for example, silicon, glass (SiO or the like), ceramics (SiN or the like), a polymeric material or the like. The substrate 2 may have a stacked structure in which an insulator layer is provided on a conductor layer.

The size of the substrate 2 is not particularly limited, but the thickness of the substrate 2 can be, for example, about 1 mm. It suffices if the length and width are selected so that it has a desired size according to the usage of the sensor 1.

The channel 3 is made of a material whose physical properties, for example, electric resistance vary as a material bonds or approaches to the channel 3. Examples of the material for the channel 3 are carbon materials such as graphene, diamond and carbon nanotube, or laminar compounds such as molybdenum disulfide (MoS₂), tungsten diselenide (WSe₂), titanium disulfide (TiS₂), phosphorus (P), or materials electrochemically stable in an oxidation-reduction region of water, such as gold (Au), platinum (Pt) and silver (Ag).

If suffices if the channel 3 is, for example, at least a single-layered atomic layer, but it may be a multi-layer. Or the channel 3 may have a shape of nanowire or nanotube. When the channel 3 is of such a shape, the channel 3 has a configuration that a plurality of wires or tubes are arranged parallel to each other with or without an interval therebetween, and one ends and the other ends of these are connected to the first electrode 4 and the second electrode 5, respectively.

The length from the one end 3a to the other end 3b of the channel 3 can be selected as desired according to the usage, but it should preferably be, for example, 10 nm to 1 mm.

When the channel 3 is graphene, the length W1 should preferably be 10 nm to 1 mm. More preferably, W1 is shorter than the crystal grain diameter of the graphene. Further, even more preferably, the length the channel 3 along the first direction, that is, a total of the lengths L1, L2 and L3, should be shorter than the crystal grain diameter of the graphene. In that case, it is possible to manufacture a highly sensitive channel 3 free of a crystal grain boundary which may cause low sensitivity. The channel 3 manufactured into such dimensions may include a crystal grain boundary, which may cause remarkably low detection sensitivity. For this reason, the difference in detection sensitivity between a channel 3 with and without a crystal grain boundary is great and prominent, and thus it becomes easy to identify a channel 3 with and without it. Thus, the channels 3 are subjected to sensitivity test, so as to select the channel 3 without a crystal grain boundary, and thus the sensor 1 with higher sensitivity can be manufactured.

A capturing body 10 may be fixed on the surface 3c of the channel 3 in a region inside the opening 7. The rapping body 10 specifically or selectively bonds to a target material in a sample (See FIG. 4 described later). Examples of the capturing body 10 are protein, peptide fragment, antibody, aptamer and nucleic acid. With the capturing body 10, it is possible to further improve the selectivity of detection of target materials. The term “fixing” means that the capturing body 10 bonds to the channel 3 any of well-known method, for example, chemical modification or interaction.

A liquid phase (not shown) which protects the capturing body 10 from drying may be provided on the surface 3c of the channel 3. Examples of the liquid phase are water, physiological solution, an ionic liquid, or a PB buffer, a PBS buffer or an organic solvent such as DMSO or an alcohol, or a mixture of any of those.

Moreover, a blocking agent 11 may be used, which prevents bonding or approaching of a material other than the target material (impurity) to the channel 3 (see FIG. 4 to be described later). The blocking agent 11 is formed, for example, so as to cover the surface 3c. Usable examples of the blocking agent 11 are a metal oxide (such as W₂O₃ or HfO₂), protein, an organic molecule and a lipid film. With the blocking agent 11, it is possible to detect target materials more specifically.

Examples of the material of the first electrode 4 and the second electrode 5 are metals such as gold (Au), silver (Ag), copper (Cu), palladium (Pd), platinum (Pt), nickel (Ni), titanium (Ti), chromium (Cr) and aluminum (Al), and conductive substances such as zinc oxide (ZnO), indium tin oxide (ITO), IGZO, and conductive polymer.

The end 3a of the channel 3 may extend into between the substrate 2 and the first electrode 4. The other end 3b may as well extend into between the substrate 2 and the second electrode 5.

The sensor 1 may further comprise an additional electrode. Or, for example, a 3-terminal type may be used, in which an additional electrode is connected to one of the end 3a and the other end 3b of the channel 3. Or a 4-terminal type may be used, in which two additional electrodes are connected to each of the one end 3a and the other end 3b of the channel 3. Or it may further comprise a gate electrode, or any type to be used for measurement of resistance, a typical example of which is a Wheatstone bridge circuit, may be used.

The material of the insulating layer 6 is, for example, an insulating material. Examples of the insulating material are ceramics of oxide film and nitride film, and an insulating polymer such as polyimide.

The substrate 2, the channel 3, the first electrode 4, the second electrode 5, and the insulating layer 6 may be constituted, for example, as a part of a detector which converts variation in physical properties of the channel 3 into an electric signal. For example, the sensor 1 may have a structure of a graphene field effect transistor (graphene FET). In that case, the channel 3 is a graphene film, and the first electrode 4 is constituted as a source electrode and the second electrode 5 is constituted as a drain electrode. The sensor 1 with such a structure may further comprise a gate electrode.

The sensor 1 is not particularly limited to graphene FET, but may have a structure of, for example, some other charge detection element, a surface plasmon resonance (SPR) element, a surface acoustic wave (SAW) element, a film bulk acoustic resonator (FEAR) element, a quartz crystal microbalance (QCM) element, or a MEMS cantilever element.

The sensor 1 can be manufactured by a semiconductor process. For example, it can be manufactured as follows.

First, an insulating film is formed on the substrate 2 for preventing discharge. When substrate 2 is already insulating, the insulating film may be omitted. Next, a sensing element including the channel 3, the first electrode 4, the second electrode 5 and the insulating layer 6, is formed on the substrate 2. An example of the sensing element which employs graphene FET will be described.

First, a graphene is formed on the substrate (wafer). As the graphene formation method, the transcription from graphite or the CVD method can be used. When using the transcription or the like, graphenes in which a pattern is formed by print technology, may be attached together. Then, the graphene is patterned. Here, a resist, a mask or the like for the patterning may remain on the graphene. Or apart from this, the graphene may be selectively formed by, for example, patterning an underlayer for formation of the graphene in advance and the subjecting it to a CVD method or the like.

After forming the graphene, the first electrode 4 and the second electrode 5 are formed in both ends of the graphene. Next, the insulating layer 6 is formed. The insulating layer 6 may be processed into a desired shape by using lithography or patterning, and may be formed by liftoff or the like using a sacrifice layer or the like. When forming the insulating layer 6, the opening 7 is formed so as to satisfy the conditions set out above. Finally, the space S such as a channel is formed.

The sensor 1 further comprises a circuit (not shown) which contains, for example, a power source which impresses voltage between the first electrode 4 and the second electrode 5 and an amperemeter which measures the value of electric current flowing between the first electrode 4 and the second electrode 5. These members may be provided, for example, in the substrate 2. Moreover, the sensor 1 may comprise pads to be connected to the first electrode 4 and the second electrode 5.

One sensing element comprising one channel 3, one first electrode 4, one second electrode 5 and one opening 7 may be disposed on one substrate 2, or a plurality of sensing elements may be provided.

Next, a method of detecting a target material in a sample using the sensor 1 of the first embodiment will be described.

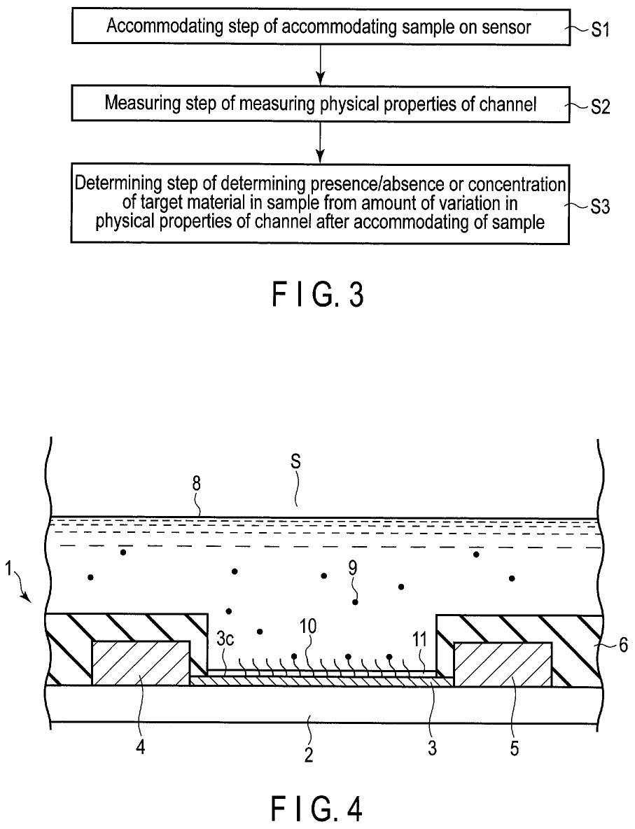

As shown in FIG. 3, the detection method, for example, comprises: (S1) an accommodating step of accommodating a sample on the sensor 1; (S2) a measuring step of measuring physical properties of the channel 3; and (S3) a determining step of determining the presence/absence or concentration of the target material in the sample from the amount of variation in physical properties of the channel 3 after the accommodation the sample. Hereafter, an example of each step will be described with reference to FIG. 4.

First, before accommodating the sample 8, the physical properties of the channel 3 may preferably be measured. By impressing voltage between the first electrode 4 and the second electrode 5 by the power source, the physical properties of the channel 3 can be measured, for example, as a value of electric current flowing between the first electrode 4 and the second electrode 5 (the first direction). Or, a measurement value before accommodation of the sample 8 obtained in the past, or a value presumed from the past knowledge may be used as the measurement value before the accommodation of the sample 8.

Next, the sample 8 is accommodated in the space S on the sensor 1. For example, the sample 8 is a liquid, which is allowed to enter the opening 7 and disposed on the surface 3c of the channel 3. Here, when the target material 9 is present in the sample 8, the target material 9 is trapped by the capturing body 10.

By this capturing, the physical properties of the channel 3 vary. The variation in physical properties is induced by, for example, a charge on the target material 9, interaction between the target material 9 and the channel 3, or formation of a hydrogen bond, though not particularly limited to these.

The physical properties are, for example, electrical conductivity, electric resistance or the like of the channel 3. For example, the variation in physical properties can be detected as an increase or decrease in value of electric current by measuring the value of the current flowing between the first electrode 4 and the second electrode 5 after accommodation of the sample 8.

The measurement of physical properties may be carried out two times, that is, before and after the accommodation of the sample 8, or may be further carried on at a timing other than these, or the properties may be monitored from before the accommodation of the sample until after the accommodation of the sample 8.

For example, when the result of the measurement indicates that the physical properties vary after the accommodation of the sample 8, it can be determined that the target material 9 is present in the sample 8. When the amount of variation is very fine or none, it can be determined that the target material 9 is not present or its amount is at the limit of detection or less. Moreover, the concentration of the target material 9 in the sample 8 may be determined from the variation in physical properties.

As described above, the target material 9 in the sample 8 can be detected by the sensor 1 of the embodiment. The sensor 1 of the embodiment has the length W1 of the channel 3 along the second direction, which is less than the length W2 of the opening 7 along the second direction (W1<W2). With this structure, detection sensitivity can be improved significantly as compared with the case where W1 is greater than W2 (W1>W2). For example, the sensitivity may improve twice as high as compared with the case of W1>W2.

A length L3 of the opening 7 along the first direction may preferably be as long as possible because, in which case, the detection sensitivity further increases. However, the length W2 of the opening 7 along the second direction has a greater influence on the detection sensitivity of the sensor 1 than the length L3 thereof along the first direction.

Therefore, the sensor 1 of the embodiment, which specifies the relationship between W1 and W2, can carry out detection at higher sensitivity.

The detection method of the embodiment may be carried out by an automatic analytic device. Such a device includes, for example: a measurement portion including the sensor 1, a power supply, an amperemeter which measures the electric current value between the first electrode 4 and the second electrode 5; a liquid transferring unit which transfers the sample 8, a liquid for forming the liquid phase, some other reagent or the like to the space S of the sensor 1; a storage unit storing the measurement data of the electric current value between the first electrode 4 and the second electrode 5, an operation formula for calculating the amount of variation in electric current value, data on the amount of variation in electric current value, data on the presence/absence or concentration of the target material 9 determined by the amount of variation, the program for controlling each unit; a data-processing unit which calculates out the amount of variation in electric current value; and a display unit which displays the amount of variation, the presence/absence, concentration or the like of the target material 9.

In this device, first, as needed, a liquid for forming a liquid phase, a reagent or the like is transferred onto the channel 3 by the liquid transfer unit. Next, in the measurement unit, the value of electric current between the first electrode 4 and the second electrode 5 is measured. At this time, the electric current value before accommodation of the sample 8 (the first measurement value) is sent to the storage unit. The sample 8 is transferred by the liquid transfer unit to the space S, then the electric current value after accommodation of the sample 8 is measured in the measurement unit and this electric current value (the second measurement value) is sent to the storage unit. Then, in the data-processing unit, the amount of variation is calculated using the operation formula, the first measurement value and the second measurement value in the storage unit. Further, the data-processing unit determines the presence/absence, concentration or the like, of the target material 9 in the sample 8 from the amount of variation. The amount of variation, or the presence/absence or concentration of the target material 9 is stored in the storage unit, and is displayed on the display unit.

The storage unit, the data-processing unit and the display unit of this device may be a computer. Each operation of this device may be carried out by manual entry of the operator of the detection method, or by the program stored in the storage unit.

The liquid sample 8 to be analyzed by the sensor 1 of the embodiment is not particularly limited, but it may be, for example, a biological material, a material of environmental origin, a material originated from food or drink, a material of industrial origin, an artificially produced formulation, or a combination of any of these. The target material 9 in the liquid sample 8 is not particularly limited, but it may be, for example, nucleic acid, protein, peptide, amino acid, a low-molecule compound, an ion, a cell, a lipid grain, an extracellular vesicle, or a virus.

The sample 8 may be a gas. The gaseous sample is not particularly limited, but it may be, for example, atmospheric air, expiration, some other gas produced from a living body or an object to be analyzed, or the surrounding air of an object to be analyzed. The target material 9 in the gaseous sample is not particularly limited, but it may be, for example, a volatile organic compound (VOC) such as an aromatic substance or a pheromone substance.

When the sample is a gas, it is preferable that a liquid phase which protects the capturing body 10 from drying and can efficiently convey the target material 9 in the gas to the capturing body 10, should be provided in advance on the surface 3c of the channel 3. A usable example of the liquid phase is one described above. The thickness of the liquid phase should preferably be thicker than 0 μm but 50 μm or less.

When the sample is a gas, the target material 9 can be detected by sending the gaseous sample into the space S.

### Second Embodiment

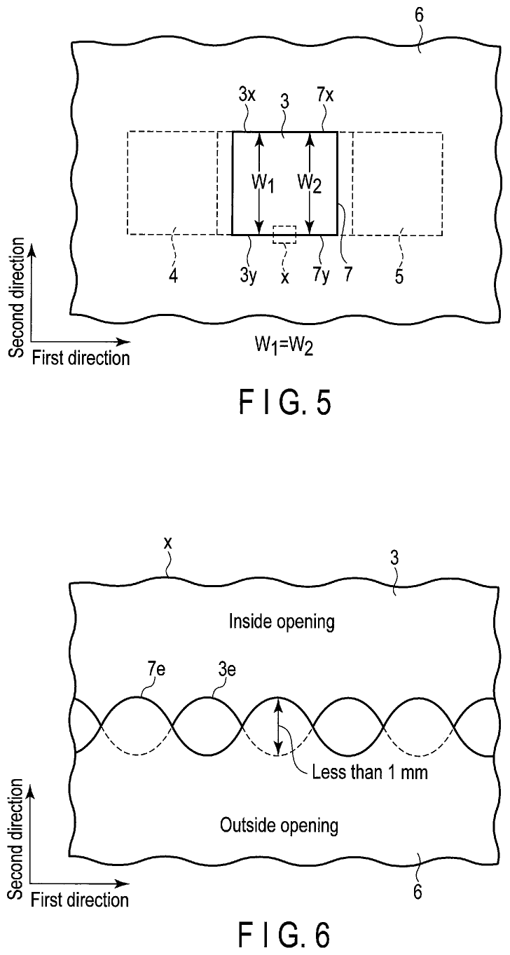

According to the second embodiment, as shown in FIG. 5, the length W1 of the channel 3 along the second direction is the same as the length W2 of the opening 7 along the second direction (W1=W2). In other words, in plain view, the edges 7x and 7y in the ends of the opening 7 along the second direction are in contact with the edges 3x and 3y in the ends of the channel 3 along the second direction, respectively. The rest of structure is similar to that of the sensor 1 of the first embodiment.

In such a case as well, the detection sensitivity is improved as compared with the case of W1>W2. Therefore, in view of the conditions of the first embodiment taken into consideration as well, the length W2 of the opening 7 along the second direction and the length W1 of the channel 3 along the second direction are equal to each other, or the length W2 of the opening 7 along the second direction is greater than the length W1 of the channel 3 along the second direction. In short, it suffices if the relation between W1 and W2 satisfies W1<W2. Here, the sensitivity of detection may be higher in the case of W1<W2 than in the case of W1=W2.

A further embodiment will now be described with reference to FIG. 6, which is an enlarged view of the enclosure X in FIG. 5. Following case is also included in the case of W1=W2, such a case is shown in FIG. 6, where at least a part of the first region R of the edge 3e, which is a line edge of the edge 3y of the channel 3, overlaps the insulating layer 6. However, it is limited to the case where the overlapping distance along the second direction between the edge 3e and the edge 7e is less than 1 mm.

Thus, if the distance is in a region of 0 mm or more but less than 1 mm, even if the insulating layer 6 overlaps with the edge 3e, the detection sensitivity is not substantially affected as compared to the case where the edge 3e and the edge 7e are in contact with each other. Therefore, such a case as well can be substantially regarded as W1=W2.

The distance should preferably be 10 μm or less because, in which case, the detection sensitivity is less affected. The distance can be measured by, for example, scanning electron microscope (SEM) analysis. For example, when a critical-dimension SEM (CD-SEM) or the like is used, a SEM image of the measurement site can be acquired, and thus the dimensions can be calculated from the magnification of images, the counted number of pixels, or the like.

Therefore, in consideration of the edges 3x and 7x of the other sides of the channel 3 and the opening 7 as well, it suffices if the relation between W1 and W2 satisfy W1<(W2−2 mm), or more preferably, W1<(W2−20 μm).

For example, when an edge of the channel 3 and the opening 7 contains line edge roughness (LER), or some other unevenness, the edge 3e and the insulating layer 6 may partially overlap each other.

In the second embodiment as well, positions of two edges of the end of the opening 7 along the first direction (length L3) may preferably be set so that, in the region of the surface 3c of the channel 3 which is not in contact with the first electrode 4 and the second electrode 5, the area overlapping the insulating layer 6 is less than 50% of the region. Or it is preferable that each of L1 and L2 should be 1 nm to 50 μm.

The sensor of the second embodiment as well can be used in a detection method and an automatic detection device similar to those of the first embodiment.

### Third Embodiment

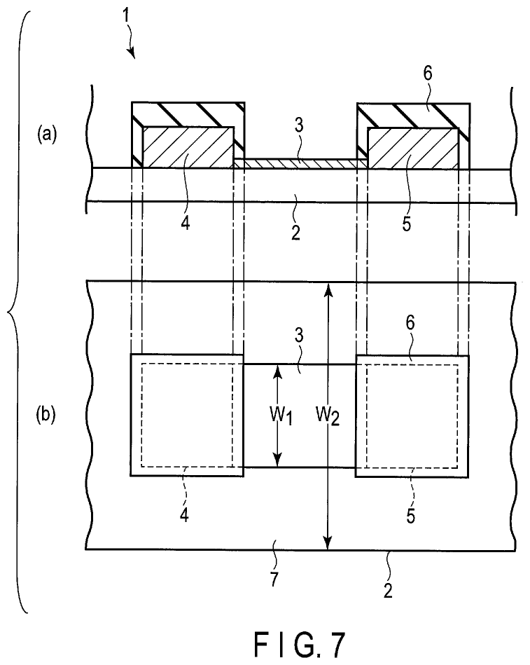

According to the third embodiment, as shown in FIG. 7, parts (a) and (b), the insulating layer 6 need not to cover the region on the substrate 2, where the first electrode 4 and the second electrode 5 are not formed. In this case, the opening 7 refers to the region on the channel 3 along the second direction, where the insulating layer 6 is not formed. Therefore, W2 extends in the second direction unless it is blocked by any member along the way, and thus the condition of W1<W2 is satisfied. For example, in some cases, there is nothing to block along the second direction, W2 may be equivalent to the length the substrate 2 along the second direction. The rest of the structure can be prepared to be similar to that of the sensor 1 of the first embodiment.

In the third embodiment as well, the length L3 should preferably be set so that, on the region of the surface 3c of the channel 3 which is not in contact with the first electrode 4 and the second electrode 5, the area overlapping the insulating layer 6 is less than 50% of the region. Or it is preferable that each of L1 and L2 should be set to 1 nm to 50 μm.

The sensor 1 of the third embodiment as well can be used in a detection method and an automatic detection device similar to those of the first embodiment.

### Fourth Embodiment

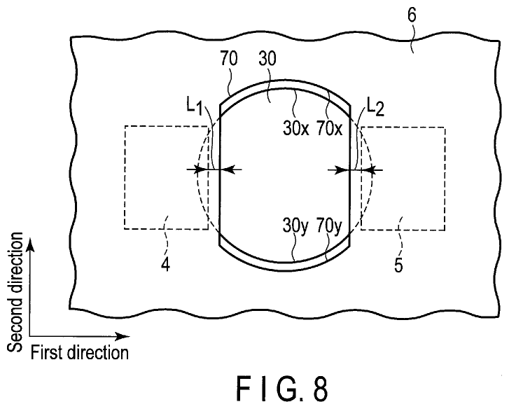

According to the fourth embodiment, the channel may be of a shape other than a rectangle. An example in which the channel is circular will be described using FIG. 8.

The first electrode 4 and the second electrode 5 are connected respectively to one end and the other end of the channel 30 along the first direction.

An edge at one end of the opening 70 along the first direction is formed substantially parallel to surfaces of the first electrode 4 and the second electrode 5, located on the side of the opening 70.

Edges at one end of the opening 70 along the second direction (namely, the edge 70x and the edge 70y) are formed into an arch shape parallel to corresponding edges of the channel 30 along the second direction (namely, the edge 30x and the edge 30y).

Here, the term “corresponding” edges are those disposed at one of the ends along the second direction, which is located on the same side. That is, the edge 30x corresponds to the edge 70x, and the edge 30y corresponds to the edge 70y.

In this example as well, the length of the opening 70 along the second direction is equivalent to the length of the channel 30 along the second direction, or the length of the opening 70 along the second direction greater than the length of the channel 30 along the second direction. In other words, the edge 70x and the edge 70y are formed so that the area (the first region R), which is the region of the edge 30x and the edge 30y overlapping the insulating layer 6 excluding ends of the lengths L1 and L2, is located inside the opening 70. The rest of the structure can be prepared to be similar to that of the sensor 1 of the first embodiment.

With any of the structure described above, the detection sensitivity is improved as compared to the cases where the edge 30x and the edge 30y are each located outside the opening 70.

Or, the phrases “the first region R being located inside the opening 70” includes the case where the first region R of the edge 30x is in contact with the edge 70x, and/or the case where the first region R of the edge 30y is in contact with the edge 70y. The word “contact” includes the case where at least a part of the first region R overlaps the insulating layer 6.

The shape of the channel is not limited to rectangular or circular, but may be of some other shape. Here, in the case of a rectangle, the direction of placement of the rectangle is not limited to that shown in FIG. 2, 5 or 7, but may be disposed along a direction rotated in an in-planar direction of the surface 3c.

Edges of the channel along the second direction are meant line edges respectively located at both ends of the channel along the second direction, and in other words, they are equivalent to two regions of the periphery of the channel, excluding the regions to which the first electrode 4 and the second electrode 5 are connected. Edges of the opening along the first direction are meant line edges respectively located at both ends of the opening along the first direction. This is also case with respect to the second direction.

The first electrode 4 and the 5th electrode should preferably be of rectangles placed along the direction indicated in FIG. 8.

The opening may be of any shape and size. But it is preferable that both edges of the opening along the first direction should be substantially parallel to the respective surfaces of the first electrode 4 and the second electrode 5 on the side of the opening.

In the channel and opening of any shape, the edges of the second direction are located inside the opening. The edges of the channel along the second direction may be in contact with the corresponding edges of the opening along the second direction. (When the maximum distance is less than 1 mm, at least part of the edges of the channel along the second direction may overlap the insulating layer.) With such a structure which satisfies these conditions, the detection sensitivity is improved further than the case where the edges of the channel along the second direction are located outside the opening.

Moreover, the above-described requirements include the configuration that the edges of the channel along the second direction are partially in contact with the edges of the openings along the second direction, and the other parts of the edges are located inside the opening.

In the fourth embodiment as well, it is preferable that the positions (length L3) of both ends of the opening along the first direction should be set so that, in region of the surface of the channel, which is not in contact with the first electrode 4 and the second electrode 5, the area overlapping the insulating layer is less than 50% of the region. Or it is preferable that the positions (length L3) of both ends of the opening along the first direction should be set so that L1 and L2 are each 1 nm to 50 μm.

The sensor 1 of the fourth embodiment as well can be used in a detection method and an automatic detection device similar to those of the first embodiment.

### EXAMPLES

Hereinafter, examples in which the sensors of the embodiments are manufactured and used will be described.

### Example 1: W1<W2

A sensor was manufactured, which comprises a substrate, a rectangular graphene film whose length W1 along the second direction is 30 μm, a first electrode connected to one end of the graphene film, a second electrode connected to the other end, and an insulating layer which covers the electrodes. The length W2 along the second direction of the opening formed on the insulating layer was 34 μm, which falls within the condition of W1<W2.

### Comparative Example 1: W1>W2

A sensor was manufactured, which comprises a substrate, a rectangular graphene film whose length W1 along the second direction is 30 μm, a first electrode connected to one end of the graphene film, a second electrode connected to the other end, and an insulating layer which covers the electrodes. The length W2 of the opening along the second direction was 10 μm, which falls within the condition of W1>W2.

The values of electric current flowing between the first electrode and the second electrode were measured using the sensors of Example 1 and Comparative Example 1. As the samples, solutions having Cl ion concentrations different from each other were accommodated on the respective sensors, and the amounts of variation in electric current value were calculated before and after replacement of the samples.

The results indicate that in Example 1, the electric current value varied by about 10%. On the other hand, with the sensor of Comparative Example 1, the electric current value varied by about 4%. Thus, it is clear that with use of the sensor of Example 1, the amount of variation about two times greater than the case of Comparative Example 1 can be obtained. The results set out above suggest that with the sensor 1 of each of the embodiments, the detection can be carried out at higher sensitivity.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A sensor comprising:
a first electrode;
a second electrode;
a channel electrically connected to the first electrode and the second electrode; and
an insulating layer which covers at least the first electrode and the second electrode and comprises an opening above the channel,
when viewed from a direction intersecting a first direction and a second direction, the first direction being a direction towards the second electrode from the first electrode, and the second direction being a direction intersecting the first direction, a length of the opening along the second direction being equivalent to or greater than the length of the channel along the second direction.

2. The sensor of claim 1, wherein
a length of a region of the channel along the first direction, which overlaps the insulating layer which covers the first electrode is 1 nm or greater but 50 μm or less, and a length of a region of the channel along the first direction, which overlaps the insulating layer which covers the second electrode is 1 nm or greater but 50 μm or less.

3. The sensor of claim 1, wherein
the opening is located so that, of a region of a surface of the channel on a side of the opening which is not in contact with the first electrode and the second electrode, an area overlapping the insulating layer is less than 50% of the region.

4. The sensor of claim 1, wherein
a case where the length of the opening along the second direction is equal to the length of the channel along the second direction, includes a case where at least a part of an edge of the channel along the second direction overlaps the insulating layer by 0 mm or greater but less than 1 mm as seen from a direction intersecting the first direction and the second direction.

5. The sensor of claim 1, wherein
the channel is of a rectangle with two sides opposing parallel to each other, to which the first electrode and the second electrode are connected respectively, and
the opening is of a rectangle, whose sides opposing parallel to each other are formed to be parallel to the parallel sides of the channel.

6. The sensor of claim 1, wherein
the insulating layer does not cover a region on the substrate, where the channel, the first electrode and the second electrode are not provided.

7. The sensor of claim 1, wherein
the channel includes a graphene film, and lengths of the channel along the first direction and the second direction are less than a crystal grain diameter of graphene.

8. The sensor of claim 1, wherein
the channel includes a graphene film, and the first electrode is a source electrode, and the second electrode is a drain electrode.

9. The sensor of claim 1, further comprising:
a capturing body specifically or selectively bonding to a target material, which is fixed on a surface of the channel, which is on a side of the opening.

10. The sensor of claim 9, wherein
the sensor is for detecting the target material in a sample.

11. A method of detecting the target material in a sample, the method comprising:
accommodating step of accommodating the sample on the sensor of claim 1;
measuring step of measuring physical properties of the channel; and
determining step of determining presence/absence or concentration of the target material in the sample from an amount of variation in the physical properties after the accommodating of the sample.
